(19) United States
(12) Patent Application Publication
(10) Pub. No.: US 2009/0093100 A1
(43) Pub. Date: Apr. 9, 2009

(54) METHOD FOR FORMING AN AIR GAP IN MULTILEVEL INTERCONNECT STRUCTURE

(76) Inventors: Li-Qun Xia, Santa Clara, CA (US); Huiwen Xu, Sunnyvale, CA (US); Mihaela Balseanu, Sunnyvale, CA (US); Meiyee (Maggie Le) Shek, Palo Alto, CA (US); Derek R. Witty, Fremont, CA (US); Hichem M'Saad, Santa Clara, CA (US)

Correspondence Address: PATTERSON & SHERIDAN, LLP - - APPM/TX, 3040 POST OAK BOULEVARD, SUITE 1500, HOUSTON, TX, 77056, US

(21) Appl. No.: 11/869,409

(22) Filed: Oct. 9, 2007

(51) Int. Cl. H01L 21/76

(52) U.S. Cl. 438/421; 257/E21.54

(57) ABSTRACT

The present invention generally provides a method for forming multilevel interconnect structures, including multilevel interconnect structures that include an air gap. One embodiment provides a method for forming conductive lines in a semiconductor structure comprising forming trenches in a first dielectric layer, wherein air gaps are to be formed in the first dielectric layer, depositing a conformal dielectric barrier film in the trenches, wherein the conformal dielectric barrier film comprises a low k dielectric material configured to serve as a barrier against a wet etching chemistry used in forming the air gaps in the first dielectric layer, depositing a metallic diffusion barrier film over the conformal low k dielectric layer, and depositing a conductive material to fill the trenches.

### BACKGROUND OF THE INVENTION

1. Field of the Invention

Embodiments of the present invention generally relate to the fabrication of integrated circuits. More particularly, embodiments of the present invention relate to methods for forming multilevel interconnect structures that include dielectric materials having low dielectric constants.

2. Description of the Related Art

Integrated circuit geometries have dramatically decreased in size since such devices were first introduced several decades ago. Since then, integrated circuits have generally followed the two year/half-size rule (often called Moore's Law), which means that the number of devices on a chip doubles every two years. Today's fabrication facilities are routinely producing devices having 0.1 μm feature sizes, and tomorrow's facilities soon will be producing devices having even smaller feature sizes.

The continued reduction in device geometries has generated a demand for films having low dielectric constant (k) values because the capacitive coupling between adjacent metal lines must be reduced to further reduce the size of devices on integrated circuits. In particular, insulators having dielectric constants less than about 3.0 are desirable. Examples of insulators having such low dielectric constants include porous dielectrics, carbon-doped silicon oxide, and polytetrafluoroethylene (PTFE).

One method that has been used to produce porous carbon doped silicon oxide films has been to deposit the films from a gas mixture comprising an organosilicon compound and a compound comprising thermally labile species or volatile groups, and then post-treat the deposited films to remove the thermally labile species or volatile groups, such as organic groups, from the deposited films. The removal of the thermally labile species or volatile groups from the deposited films creates nanometer-sized voids in the films, which lowers the dielectric constant of the films, e.g., to about 2.5.

Formation of large air gaps consisted of nanometer-sized voids will further reduce dielectric constant because air has a dielectric constant of approximately 1. However, thermal processes used in large air gap formation have several problems. For example, thermal removal creates stress in the structure, which presents stability problems.

Therefore, in view of the continuing decrease in integrated circuit feature sizes and existing problems in the conventional methods, there remains a need for a method of forming dielectric layers having dielectric constants lower than 3.0.

### SUMMARY OF THE INVENTION

The present invention generally provides methods for forming multilevel interconnect structures, including multilevel interconnect structures that include uniform air gaps encapsulated in smaller features.

One embodiment provides a method for forming conductive lines in a semiconductor structure comprising forming trenches in a first dielectric layer, wherein air gaps are to be formed in the first dielectric layer, depositing a conformal dielectric barrier film in the trenches, wherein the conformal dielectric barrier film comprises a low k dielectric material configured to serve as a barrier against a wet etching chemistry used in forming the air gaps in the first dielectric layer, depositing a metallic diffusion barrier film over the conformal low k dielectric layer, and depositing a conductive material to fill the trenches.

Another embodiment provides a method for forming a dielectric structure having air gaps comprising forming trenches in a first dielectric layer, wherein the trenches are configured to retain conductive materials therein, depositing a first conformal dielectric barrier film in the trenches, depositing a first conductive material to fill the trenches, planarizing the first conductive material to expose the first dielectric layer, forming a first self-aligned capping layer on the conductive material, depositing a first porous dielectric barrier over the first conductive material and the first dielectric layer, and forming air gaps between the trenches by removing the first dielectric layer using a wet etching solution through the first porous dielectric barrier, wherein the first conformal dielectric barrier film serves as a barrier and etch stop against the wet etching solution.

Yet another embodiment provides a method for forming a dielectric structure having air gaps comprising forming trenches in a first dielectric layer, wherein the trenches having angled sidewalls and are narrow at bottoms and wide at openings, depositing a first conformal dielectric barrier film in the trenches, depositing a first conductive material to fill the trenches, planarizing the first conductive material to expose the first dielectric layer, removing the first dielectric layer to form reversed trenches around the first conductive material, wherein the reversed trenches have angled sidewalls and are narrow at openings and wide at bottoms, and forming air gaps at least in part of reversed trenches by depositing a first non-conformal dielectric layer in the reversed trenches, wherein air gaps are formed in the reversed trenches having an aspect ratio larger than a particular value.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIGS. 1A-1J schematically illustrate cross-sectional views of a substrate stack during a processing sequence to form multilevel interconnect structures according to an embodiment of the invention.

FIGS. 2A-2J schematically illustrate cross-sectional views of a substrate stack during a processing sequence to form multilevel interconnect structures according to another embodiment of the invention.

FIGS. 3A-3F schematically illustrate cross-sectional views of a substrate stack during a processing sequence to form multilevel interconnect structures according to another embodiment of the invention.

FIG. 4 illustrates processing steps in accordance with the processing sequence shown in FIGS. 1A-1J.

FIG. 5 illustrates processing steps in accordance with the processing sequence shown in FIGS. 2A-2J.

FIG. 6 illustrates processing steps in accordance with the processing sequence shown in FIGS. 3A-3F.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the present invention generally provide a method for forming air gaps in multilevel interconnect structures. The air gaps are generally formed at areas wherein metal structures are densely packed, for example in a trench level of a damascene structure. A conformal low k dielectric barrier film is deposited around metal structures to provide mechanical support around the air gaps and to protect metal structures from wet etching chemistry and moisture during air gap formation. A unique porous low k dielectric layer is formed above a removable interlayer dielectric (ILD) layer. The porous dielectric barrier serves as a membrane to allow penetration of wet etching chemistry and to allow removal of the ILD layer and formation of air gaps therein. A dense dielectric barrier is then deposited above the porous dielectric barrier. A low stress low k ILD layer may be deposited over the dense dielectric barrier providing dielectric for forming structures in the next level. The low stress ILD layer reduces stress caused by the formation of air gaps within the multilevel interconnect structure. In another embodiment, a non-conformal low k dielectric layer is deposited around metal structures with sloped sidewall and air gaps may be formed within portions of the non-conformal low k layer where metal structures are densely packed.

Forming Air Gaps through a Porous Dielectric Barrier

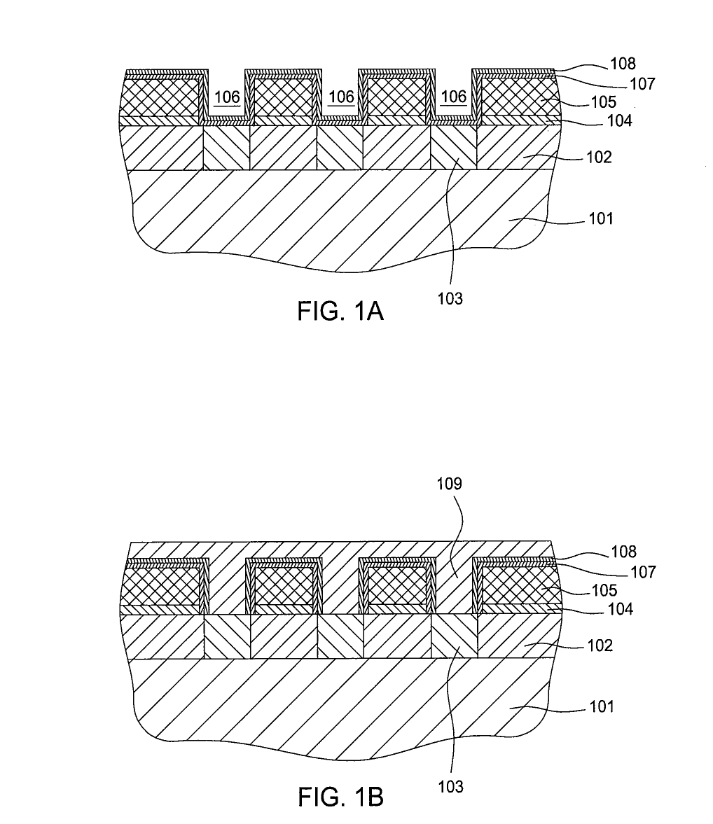

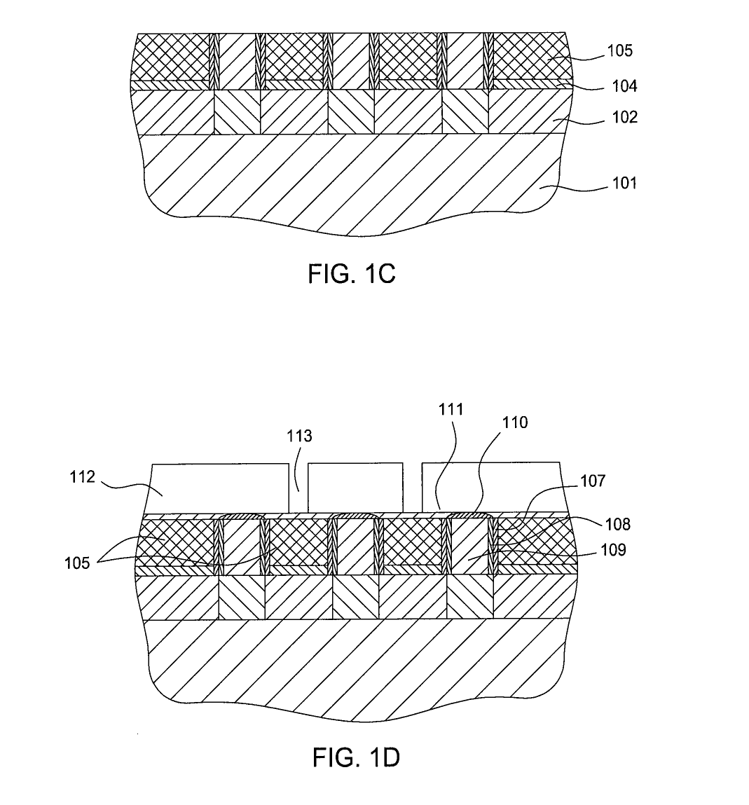

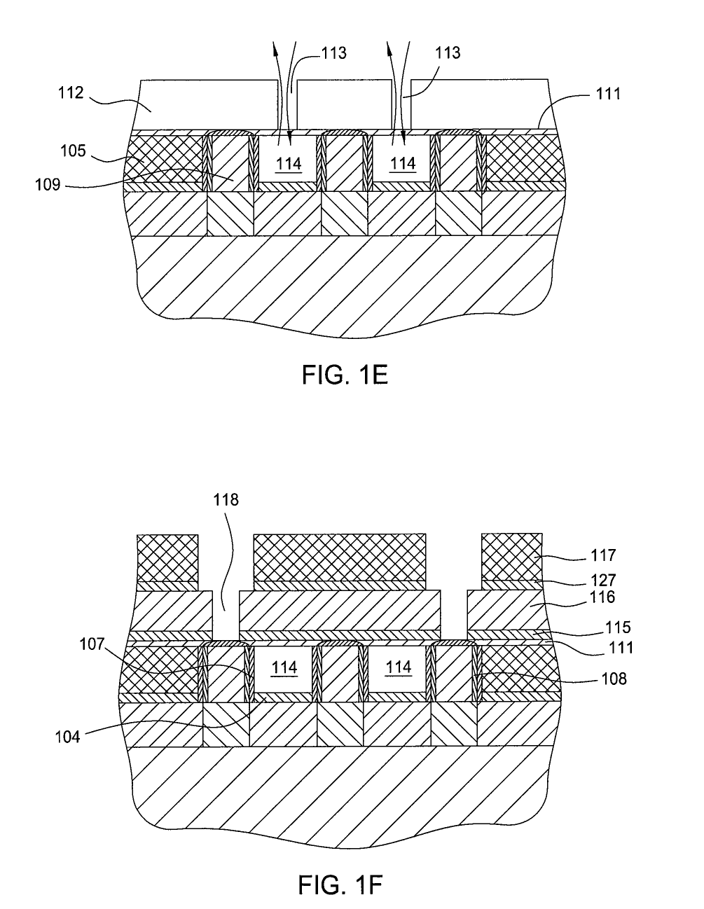

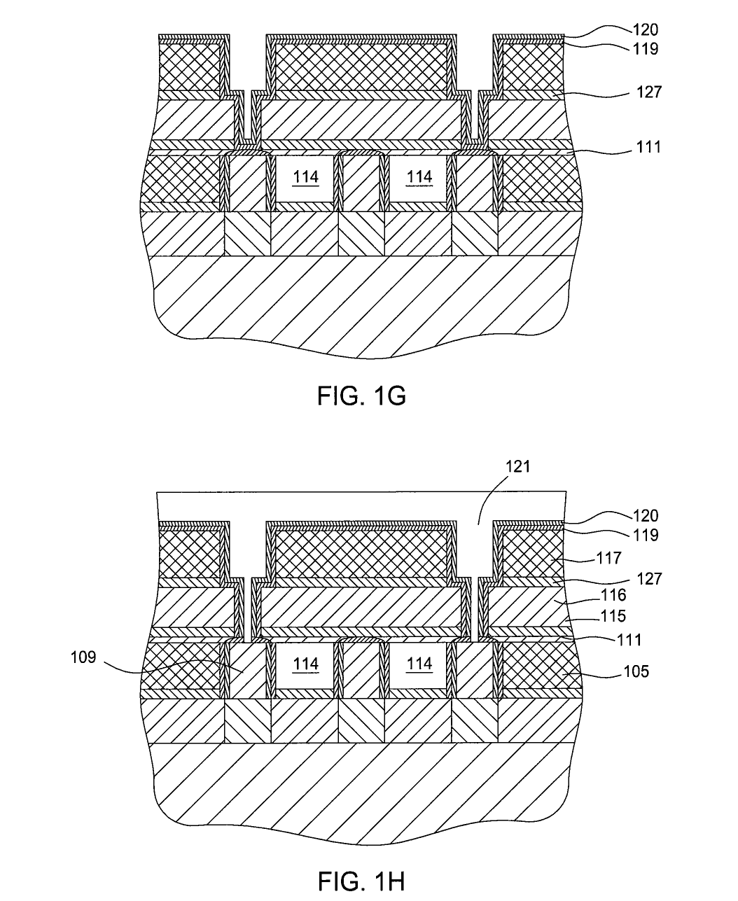

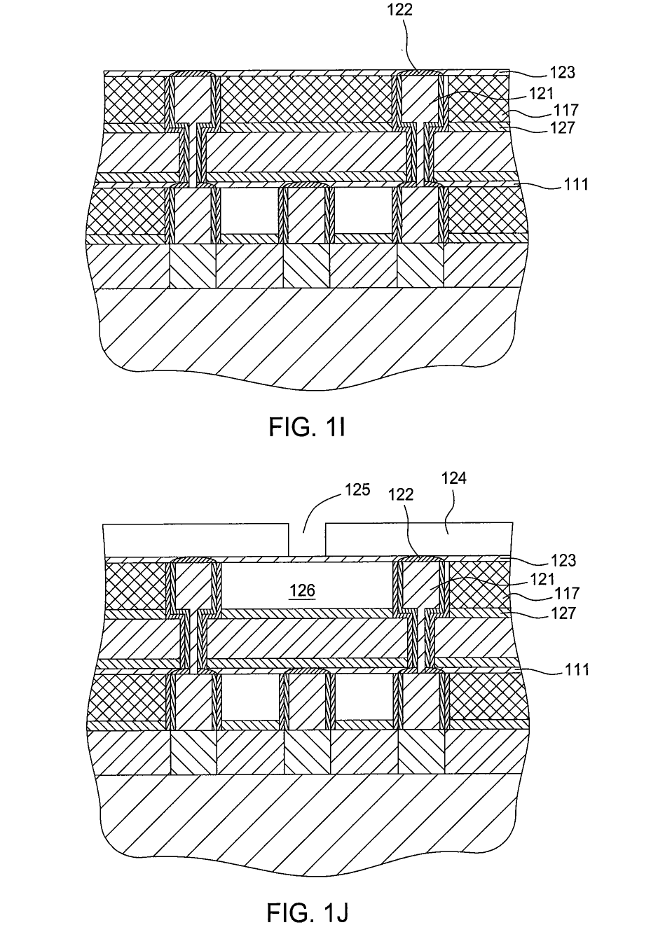

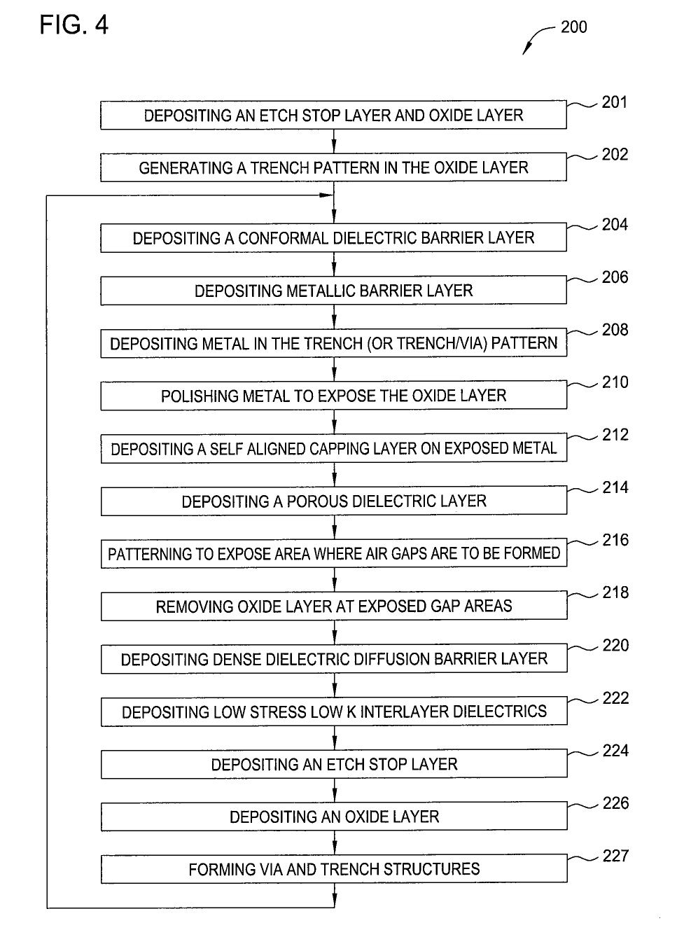

FIGS. 1A-1J schematically illustrate cross-sectional views of a substrate stack during a processing sequence to form multilevel interconnect structures according to an embodiment of the invention. FIG. 4 illustrates a process 200 in accordance with the processing sequence shown in FIGS. 1A-1J.

After devices, such as transistors, are formed on a semiconductor substrate 101, a via layer 102 may be formed on the substrate 101. The via layer 102 is typically a dielectric film having conductive elements (vias) 103 formed therein. The conductive elements 103 are configured to electrically communicate with the devices formed in the substrate 101. Multilevel interconnect structures, typically including alternate trench layers and via layers of conductive materials and dielectrics, are formed on the via layer 102 to provide circuitry for the devices in the substrate 101. A trench layer generally refers to a dielectric film having conductive lines are formed. A via layer is a layer of dielectrics having small metal vias that provide electrical pathways from one trench layer to another trench layer.

The process 200 provides a method for forming multilevel interconnect structures over the via layer 102.

In step 201, an etch stop layer 104, shown in FIG. 1A, is deposited all over the via layer 102, and a first dielectric layer 105, for example, a silicon dioxide layer, is deposited on the etch stop layer 104. The etch stop layer 104 is configured to protect the via layer 102 during a subsequent etching step and to serve as a dielectric diffusion barrier. The etch stop layer 104 may be a silicon carbide layer.

In step 202, trenches 106 is formed in the dielectric layer 105 and the etch stop layer 104. The trenches 106 may be formed using any conventional method known to those skilled in the art, such as patterning using photoresist, followed by etching.

In step 204, a conformal dielectric barrier film 107 is deposited over the entire top surface of the substrate including sidewalls of the trenches 106. The conformal dielectric barrier film 107 is configured to serve as a barrier layer to protect metal structures, such as copper lines, subsequently formed in the trenches 106 from wet etching chemistry and moisture during the subsequent process. Additionally, the conformal dielectric barrier film 107 also provides mechanical support to the metal structures formed in the trenches 106 after air gaps are formed therearound. In one embodiment, the conformal dielectric barrier film 107 comprises a low k dielectric barrier material, for example boron nitride (BN), silicon nitride (SiN), silicon carbide (SiC), silicon carbine nitride (SiCN), silicon boron nitride (SiBN), or the combinations thereof.

In one embodiment, the conformal dielectric barrier film 107 is a boron nitride (BN) layer, with a k value less than about 5.0, formed by a plasma enhance chemical vapor deposition (PECVD) process. The conformal dielectric barrier film 107 may have a thickness from about 10 Å to about 200 Å. Depositing the boron nitride layer may comprise forming a boron-containing film from a boron-containing precursor, and treating the boron-containing film with a nitrogen-containing precursor. Forming the boron-containing film may be performed with or without a presence of plasma. The boron-containing precursor may be diborane (B₂H₆), borazine (B₃N₃H₆), or an alkyl-substituted derivative of borazine. Treating the boron-containing film may be selected from the group consisting of a plasma process, an ultraviolet (UV) cure process, a thermal anneal process, and combinations thereof. The nitrogen-containing precursor may be nitrogen gas (N₂), ammonia (NH₃), or hydrazine (N₂H₄). Detailed description of depositing a boron nitride film may be found in U.S. Provisional Patent Application Ser. No. 60/939,802, entitled “Boron Nitride and Boron-Nitride Derived Materials Deposition Method” (Attorney Docket No. 11996), filed May 23, 2007, which is incorporated herein by reference.

In step 206, a metallic diffusion barrier 108 is formed above the conformal dielectric barrier film 107. The metallic diffusion barrier 108 is configured to prevent diffusion between metal lines subsequently deposited in the trenches 106 and the dielectric structures nearby. The metallic diffusion barrier 108 may comprise tantalum (Ta) and/or tantalum nitride (TaN).

In step 208, the trenches 106 may be filled with conductive lines 109 comprising one or more metals, as shown in FIG. 1B. In one embodiment, a sputtering step may be performed to remove the metallic diffusion barrier 108 and the conformal dielectric barrier film 107 from entire or portions of bottom walls of the trenches 106, so that the conductive lines 109 may be in direct contact with the conductive elements 103 in the via layer 102. Depositing the conductive lines 109 may comprise forming a conductive seed layer and depositing a metal on the conductive seed layer. The conductive lines 109 may comprise copper (Cu), aluminum (Al), or any suitable material with desirable electrical conductivity.

In step 210, a chemical mechanical polishing (CMP) process is performed on the conductive lines 109, the metallic diffusion barrier 108, and the conformal dielectric barrier film 107 so that the dielectric layer 105 is exposed, as shown in FIG. 1C.

In step 212, a self-aligned capping layer 110 is formed on the conductive lines 109. The self-aligned capping layer 110 may be formed using electroless deposition and formed only on the exposed surface of the conductive lines 109. The self-aligned capping layer 110 is configured to be a barrier to protect the conductive lines 109 from wet etching chemistry used in air gap formation and to prevent diffusion of species across an upper surface of the conductive lines 109. The self-aligned capping layer 110 may prevent diffusion of both copper and oxygen. For the conductive lines 109 comprise copper, the self-aligned capping layer 110 may comprise a variety of compositions containing cobalt (Co), tungsten (W) or molybdenum (Mo), phosphorus (P), boron (B), rhenium (Re), and combinations thereof. Detailed descriptions for forming the self-aligned capping layer 110 may be found in the United States Patent Publication No. 2007/0099417, entitled “Adhesion and Minimizing Oxidation on Electroless Co Alloy Films for Integration with Low k Inter-Metal Dielectric and Etch Stop”, which are incorporated herein by reference.

In step 214, a porous dielectric barrier 111 is deposited on the conductive lines 109 and the conformal dielectric barrier film 107. The porous dielectric barrier 111 may be a low k dielectric barrier with k<4.0. The porous dielectric barrier 111 is permeable allowing etching solution, such as diluted hydrogen fluoride (DHF) solution, to infiltrate into a removable layer, such as the first dielectric layer 105, underneath to form air gaps. The porous dielectric barrier 111 is carbon rich and hydrophobic. The porous dielectric barrier 111 generally has a low wet etching rate such that contacting with etching solution does not affect its structure. In one embodiment, a low wet etching rate may be achieved by reducing or eliminating Si—O bonds in the porous dielectric barrier 111. In one embodiment, the porous dielectric barrier 111 may also serve as a diffusion barrier layer for metals, such as copper, in the conductive lines 109. In one embodiment, the porous dielectric barrier 111 is hydrophobic, therefore, minimizing residues and contamination from wet etching process. In one embodiment, hydrophobicity of the porous dielectric barrier 111 may be acquired by controlling carbon content in the porous dielectric barrier 111.

In one embodiment, the porous dielectric barrier 111 comprises silicon carbide (SiC), silicon carbide nitride (SiCN), or combinations thereof, without silicon oxygen bonds (Si—O). In one embodiment, the porous dielectric barrier 111 may have a thickness of between about 10 Å to about 100 Å. In another embodiment, the porous dielectric barrier 111 may have a thickness of between about 50 Å to about 300 Å.

The porous dielectric barrier 111 may be formed using chemical vapor deposition using silicon and carbon containing precursors. In one embodiment, low density plasma condition is used to form the porous dielectric barrier 111. In one embodiment, the porous dielectric barrier 111 may a silicon carbide layer deposited by reacting a processing gas comprising hydrogen and an oxygen-free organosilicon compound similar to method for depositing low k silicon carbide layer in U.S. Pat. No. 6,790,788, entitled “Method of Improving Stability in Low k Barrier Layers”, which is herein incorporated by reference.

Detailed description of method for forming the porous dielectric barrier may be found in the U.S. patent application Ser. No. ______ (Attorney Docket No. 11498), filed Oct. 9, 2007, entitled “Method to Obtain Low K Dielectric Barrier with Superior Etch Resistivity”, which is incorporated herein as reference. Example 1 lists an exemplary recipe for depositing the porous dielectric barrier 111.

### EXAMPLE 1

A PECVD deposition process for depositing a porous dielectric barrier having silicon carbide comprises using a precursor comprising the combination of trimethylsilane (TMS, (CH₃)₃SiH) and ethylene (C₂H₄). The process conditions, including the ratio of TMS and ethylene, are set such that the atomic percentage of carbon is greater than 15%. In one embodiment, the ratio of ethylene and TMS is about 1:1 to about 8:1, the flow rate of the TMS/ethylene precursor and carrier gas is between about 5 sccm to about 10,000 sccm, and the temperature is about 350° C. For these conditions, the chamber pressure is between about 10 mTorr to about one atmosphere, the radio frequency (RF) power for plasma generation is between about 15 W to about 3,000 W, and the spacing between a substrate and a shower head, configured for providing precursors to the substrate being processed, is from about 200 mils to about 2000 mils.

Returning to FIG. 4, in step 216, a pattern may be generated to expose areas wherein air gaps are to be formed. A photoresist layer 112 is deposited on the porous dielectric barrier 111. A pattern is then developed in the photoresist layer 112 exposing portions of the porous dielectric barrier 111 via holes 113, as shown in FIG. 1D. The pattern is used to limit air gaps in areas where distance between the conductive lines 109 is in certain range. For example, air gaps may be limited in areas where distance between neighboring conductive lines 109 is greater than 5 nm. Air gaps are most effective to lower k value of dielectrics between closely packed conductive lines 109. Additionally, forming an air gap between far away metal structures, such as the conductive lines 109 with large pitch, or vias in a via layer, may effect integrity of the mechanical structure. Therefore, the pattern is formed in this step to limit air gaps in certain range. In one embodiment, air gaps may be formed between neighboring conductive lines 109 where the distance between the conductive lines 109 is between about 5 nm to about 200 nm.

In step 218, a wet etching process is performed. Portions of the first dielectric layer 105 contact an etching solution, such as DHF solution, through the porous dielectric barrier 111 exposed by the holes 113, and are completely or partially etched away forming air gaps 114, as shown in FIG. 1E. In one embodiment, the DHF solution comprises 6 parts of water and 1 part of hydrogen fluoride. Other wet etching chemicals, such as buffered hydrogen fluoride (BHF, NH₄F+HF+H₂O), may also be used to etch the first dielectric layer 105 via the porous dielectric barrier 111. Exemplary etching methods may be found in U.S. Pat. No. 6,936,183, entitled “Etch Process for Etching Microstructures”, which is herein incorporated by reference. The etching solution reaches the first dielectric layer 105 through the porous dielectric barrier 111 and the etching products is removed through the porous dielectric barrier 111, as shown in FIG. 1E by arrows.

The etching process is controlled by the conformal dielectric barrier film 107, the etch stop layer 104 and the porous dielectric barrier 111 surrounding the first dielectric layer 105. The conformal dielectric barrier film 107 and the porous dielectric barrier 111 also provide uniform structure to the air gaps 114. A cleaning process may be followed by the etching process to remove the photoresist and residues of the etching process.

In step 220, a dense dielectric barrier 115, shown in FIG. 1F, is deposited on the porous dielectric barrier 111 upon completion of air gap formation. The dense dielectric barrier 115 is configured to prevent diffusion of metals, such as copper, in the conductive lines 109, and migration of moisture in the air gaps 114. The dense dielectric barrier 115 may comprises a thin low k dielectric barrier film, such as silicon carbide (SiC), silicon carbide nitride (SiCN), boron nitride (BN), silicon boron nitride (SiBN), silicon boron carbide nitride (SiBCN), or combinations thereof. In one embodiment, the dense dielectric barrier 115 has a thickness of between about 20 Å to about 500 Å. In another embodiment, the dense dielectric barrier 115 has a thickness of between about 50 Å to about 200 Å.

In step 222, an ILD layer 116 is deposited on the dense dielectric barrier 115. Any suitable dielectric materials may be used as the ILD layer 116. In one embodiment, the ILD layer 116 is a low k and low stress dielectric with a dielectric constant k<2.7 between trench layers. The low stress in the ILD layer 116 enables the ILD layer 116 to absorb and/or neutralize stress generated by the formation of the air gaps 114. The ILD layer 116 also has good mechanical properties for supporting the structure. In one embodiment, the ILD layer 116 has a thickness of between about 100 Å to about 5,000 Å. The ILD layer 116 may be carbon doped silicon dioxide, siliconoxycarbide (SiOₓC_{y}), or combinations thereof. Method for forming the ILD layer 116 may be found in United States Patent Publication No. 2006/0043591, entitled “Low Temperature Process to Produce Low-K Dielectrics with Low Stress by Plasma-Enhanced Chemical Vapor Deposition (PECVD)”, which is herein incorporated by reference.

In step 224, an etch stop layer 127 is formed on the ILD layer 116. The etch stop layer 127 is configured to protect the ILD layer 116 from wet etching chemistry used in forming air gaps in a subsequent trench layer above the ILD layer 116. In one embodiment, the etch stop layer 127 may comprise silicon carbide.

In step 226, a second dielectric layer 117 is formed on the etch stop layer 127. The second dielectric layer 117 may be similar to the first dielectric layer 105. In one embodiment, the second dielectric layer 117 comprises silicon dioxide.

In step 227, as shown in FIG. 1F, a conventional dual damascene structure 118 may be formed in the ILD layer 116 and the second dielectric layer 117 for forming a new via layer and a new trench layer therein respectively. A detailed description for forming a dual damascene structure may be found in United States Patent Application Publication No. 2006/0216926, entitled “Method of Fabricating a Dual Damascene Interconnect Structure”, which is herein incorporated by reference.

As shown in FIGS. 1G-1J, steps 204 to 218 may be repeated to form air gaps 126 between conductive lines 121 formed in the second dielectric layer 117. A conformal dielectric barrier film 119, similar to the conformal dielectric barrier film 107, may be deposited in the dual damascene structure 118 prior to deposition of a metallic diffusion barrier layer 120, similar to the barrier layer 108. Conductive lines 121 may be formed in the damascene structure 118 after a punch through step. A cap layer 122, similar to the self-aligned capping layer 110, and a porous dielectric barrier 123, similar to the porous dielectric barrier 111, may be formed after a CMP process. The photoresist layer 124 may be deposited on the porous dielectric barrier 123, and a pattern formed in the photoresist exposing portions of the second dielectric layer 117 through holes 125 in the photoresist layer 124. A wet etching process is then be used to form the air gaps 126.

Similarly, air gaps may be formed in selected regions of each sequential dielectric layer using the process described above.

The air gap formation process described above has several advantages over conventional air gap formation methods, for example, thermal decomposition.

First, the conformal low k dielectric barrier, such as the conformal dielectric barriers 107 and 119, not only serves as a good dielectric barrier to protect metal, such as copper, from moisture and chemical solution used in sequential steps, but also provides mechanical support to conductive lines after air gap formation.

Second, compared to the thermal decomposition, embodiments of the present invention uses selective wet etching method to form uniform air gaps. Particularly, wet etch chemicals such as DHF and BHF, are used to remove formed dielectrics such as SiO₂ to form an air gap. Thermal decomposition can not be selective. All the disposable materials will be removed or damaged and any remaining disposable materials in the structure may cause reliability issue in the subsequent process steps. The wet etching method used in the present invention may be selective and apply only to selected area via photolithography and patterning steps. Therefore, area percentage and location of air gap can be designed to meet desired dielectric value as well as necessary mechanical strength. For example, air gaps may be formed in the dense metal areas where pitch length between the two adjacent metal lines is between 10 nm and 200 nm.

Third, a low stress low dielectric layer is be used in the interlayer dielectrics to minimize the stress of the whole stack and also provide strong mechanical support to the whole interconnect structure.

Fourth, a porous dielectric barrier film permeable to wet etching chemicals is used as membrane to allow the wet etching solution to infiltrate into removable dielectric layer underneath to form an air gap.

Fifth, a thin dense hermetic dielectric barrier film, such as the barrier layer 115, is deposited on top of porous dielectric barrier film to prevent diffusion as well as moisture penetration.

### Forming Air Gaps in a Non-Conformal Dielectric Layer

Embodiments of the present invention also provide method for generating air gaps by depositing a non-conformal dielectric layer in trenches between conductive lines. Trenches with angled sidewalls may be formed in a dielectric layer by a controlled etching process. The sidewalls are angled such that the trenches have openings wider than bottoms. A conformal dielectric barrier is deposited on trench surfaces to provide barrier from wet etching chemistry. The trenches with angled sidewalls are then filled with conductive materials forming conductive lines. The dielectric layer around the conductive lines is removed leaving reversed trenches between the conductive lines. The reversed trenches between the conductive lines have angled sidewalls with openings narrower than bottoms. A non-conformal dielectric layer is then deposited in the trenches between the conductive lines. The deposition process may be controlled such that air gaps form within narrow trenches. While a solid dielectric layer is formed where the trenches are wide. Thus, the air gap formation is naturally selective without using a mask. Two exemplary processing sequences are described below.

### Sequence 1

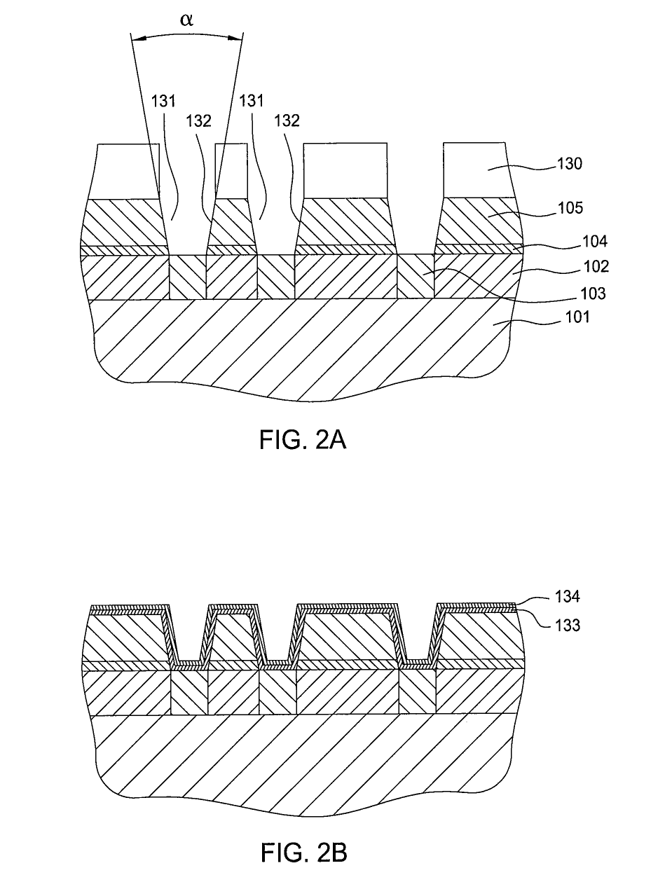

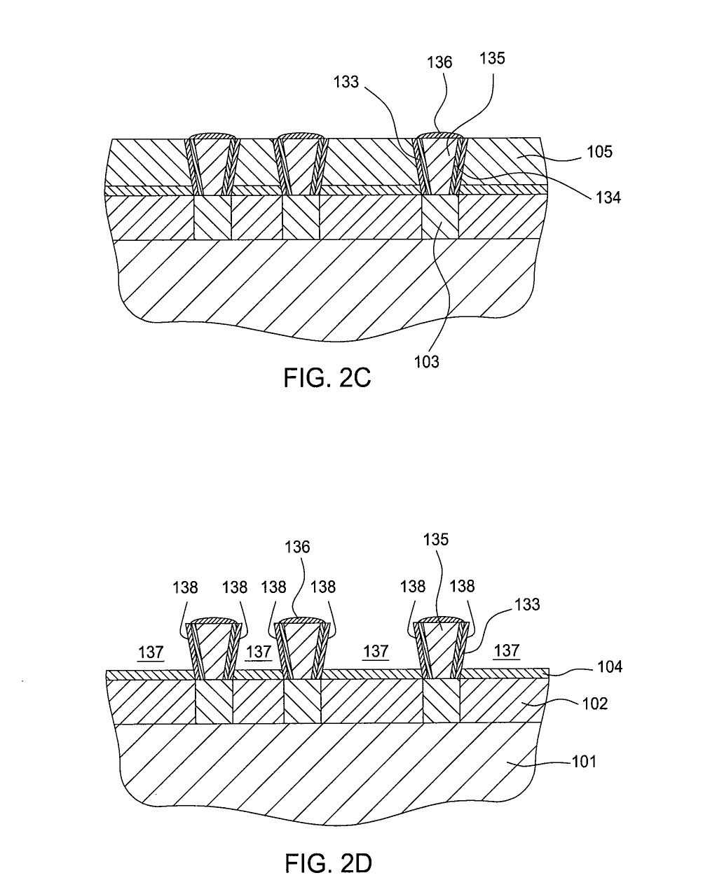

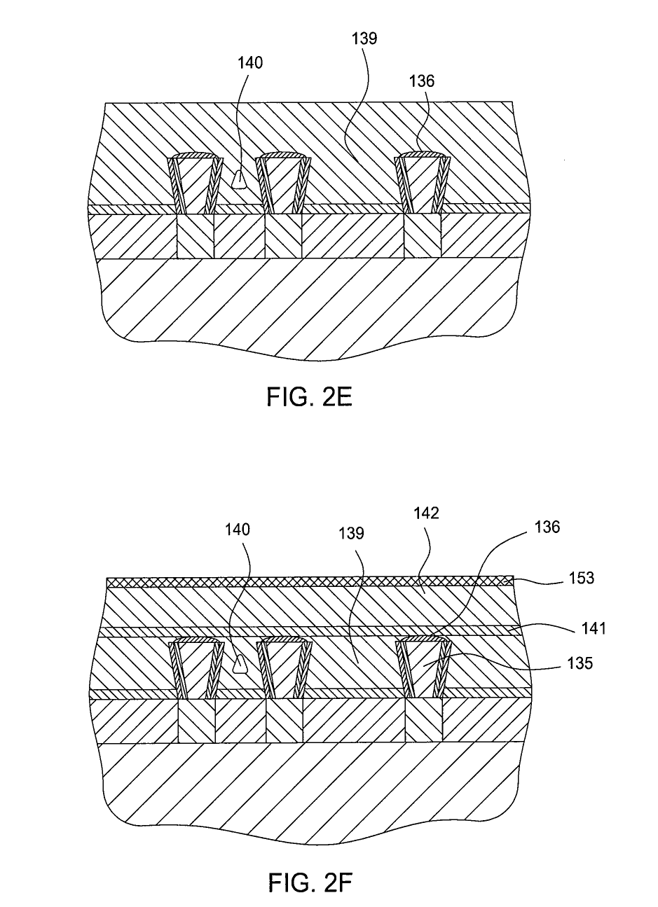

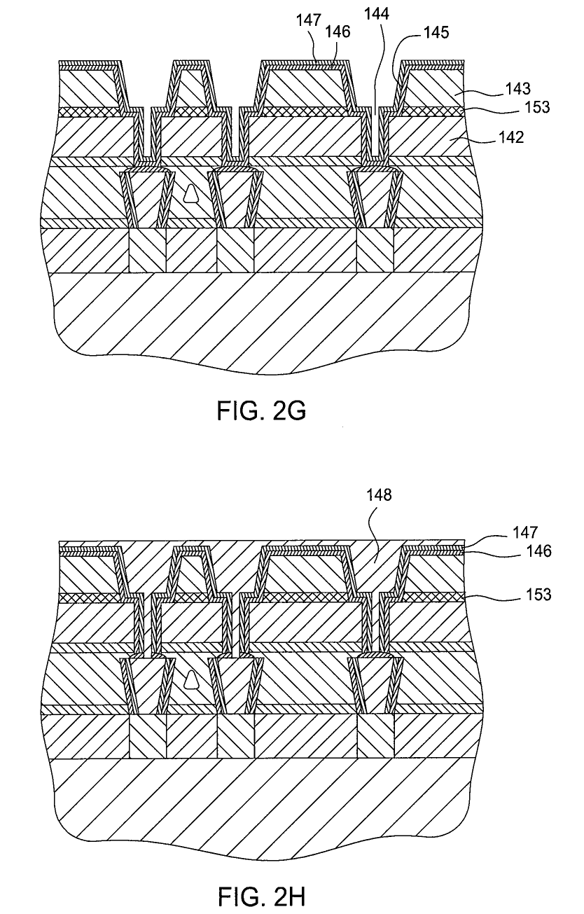

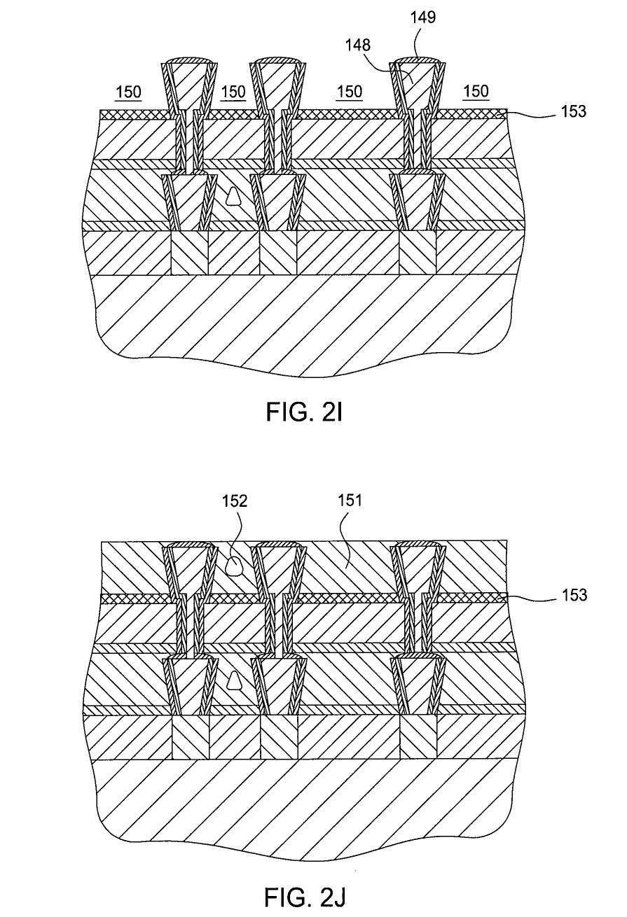

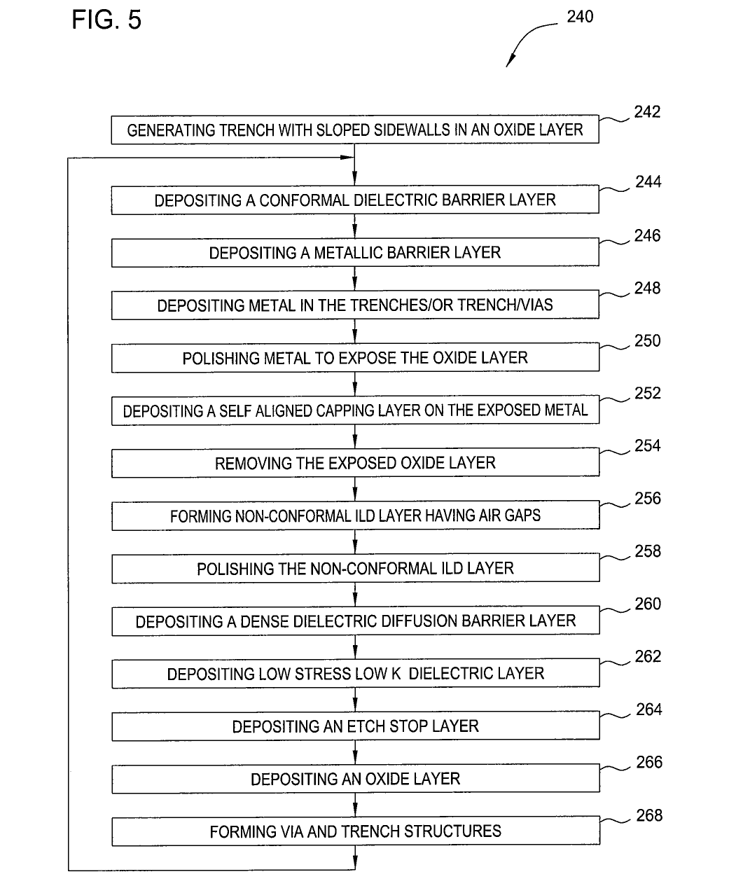

FIGS. 2A-2J schematically illustrate cross-sectional views of a substrate stack during a processing sequence 240 to form multilevel interconnect structures according to one embodiment of the invention. FIG. 5 illustrates processing steps in accordance with the processing sequence 240 shown in FIGS. 2A-2J.

As shown in FIG. 2A, after devices, such as transistors, are formed on the semiconductor substrate 101, the via layer 102 may be formed on the substrate 101. The conductive elements 103 are configured to electrically communicate with the devices formed in the substrate 101. The etch stop layer 104 is then deposited all over the via layer 102. The first dielectric layer 105, for example, a silicon dioxide layer, is deposited on the etch stop layer 104.

In step 242, trenches 131 with angled sidewalls 132 are generated by an etching process through a pattern formed in a photoresist 130. The etching process is generally less anisotropic compared to conventional etching processes used in forming trenches with vertical walls. In one embodiment, isotropic plasma etching process may be used to form the trenches 131 with angled sidewalls 132. Angles of the sidewalls 132 may be tuned by adjusting processing parameters, for example the level of bias power. In one embodiment, the angle α between opposite sidewalls 132 of the trench 131 may be in the range of about 5° to about 130°.

In step 244, a conformal dielectric barrier film 133 is deposited over the trenches 131 after removing portions of the etch stop layer 104 and the photoresist 130, as shown in FIG. 2B. The conformal dielectric barrier film 133 is configured to serve as a barrier layer to protect metal structures, such as copper lines subsequently formed in the trenches 131, from moisture and or chemicals during process. Additionally, the conformal dielectric barrier film 133 also provides mechanical support to the metal structures formed in the trenches 131 after air gaps are formed therearound. In one embodiment, the conformal dielectric barrier film 133 comprises silicon nitride (SiN). The conformal dielectric barrier film 133 may comprise any suitable low k dielectric materials, such as, boron nitride (BN), silicon nitride (SiN), silicon carbide (SiC), silicon carbine nitride (SiCN), silicon boron nitride (SiBN), or the combinations thereof. The conformal dielectric barrier film 133 may be deposited using similar process described in step 204 of FIG. 4 for deposition of the conformal dielectric barrier film 107.

In step 246, a metallic diffusion barrier 134 is formed above the conformal dielectric barrier film 133, as shown in FIG. 2B. The metallic diffusion barrier 134 is configured to prevent diffusion between metal lines subsequently deposited in the trench 131 and the structures nearby. The dense dielectric barrier may comprise tantalum (Ta) and/or tantalum nitride (TaN).

In step 248, the trenches 131 may be filled with conductive lines 135 comprising one or more metals, as shown in FIG. 2C. In one embodiment, a sputtering step may be performed to remove the metallic diffusion barrier 134 and the conformal dielectric barrier film 133 from entire or portions of bottom walls of the trenches 131, so that the conductive lines 135 may be in direct contact with the conductive elements 103 in the via layer 102. Depositing the conductive lines 135 may comprise forming a conductive seed layer and depositing a metal on the conductive seed layer. The conductive lines 135 may comprise copper (Cu), aluminum (Al), or any suitable material with desirable electrical conductivity.

In step 250, a chemical mechanical polishing (CMP) process is performed on the conductive lines 135, the metallic diffusion barrier 134, and the conformal dielectric barrier film 133 so that the dielectric layer 105 is exposed, as shown in FIG. 2C.

In step 252, a self-aligned capping layer 136 is formed on the conductive lines 135. The self-aligned capping layer 136 is configured to be a barrier to prevent diffusion of species on an upper surface of the conductive lines 135. The self-aligned capping layer 136 may prevent diffusion of both copper and oxygen. The self-aligned capping layer 136 may be formed using electroless deposition and formed only on the exposed surface of the conductive lines. The self-aligned capping layer 136 is configured to be a barrier to protect the conductive lines 135 from wet etching chemistry used in air gap formation and to prevent diffusion of species across an upper surface of the conductive lines 135. The self-aligned capping layer 136 may prevent diffusion of both copper and oxygen. For the conductive lines 135 comprise copper, the self-aligned capping layer 136 may comprise a variety of compositions containing cobalt (Co), tungsten (W) or molybdenum (Mo), phosphorus (P), boron (B), rhenium (Re), and combinations thereof. Detailed descriptions for forming the self-aligned capping layer 136 may be found in the United States Patent Publication No. 2007/0099417, entitled “Adhesion and Minimizing Oxidation on Electroless Co Alloy Films for Integration with Low k Inter-Metal Dielectric and Etch Stop”, which are incorporated herein by reference.

In step 254, an etching process may be performed to remove the first dielectric layer 105 forming reversed trenches 137 between the conductive lines 135, as shown in FIG. 2D. The reversed trenches 137 have angled sidewalls 138 which make the reversed trenches 137 narrow at openings and wide at bottoms. Wet or dry etching process may be used to remove the first dielectric layer 105. The reversed trenches 137 are lined with the etch stop layer 104 and the conformal dielectric barrier film 133, which protect the via layer 102 and the conductive lines 135 during etching respectively.

In step 256, a non-conformal dielectric layer 139 is deposited in the reversed trenches 137 with angled sidewalls, as shown in FIG. 2E. The non-conformal dielectric layer 139 comprises a low k, for example k≦2.7, low stress interlayer dielectric film with good mechanical properties to support structures in the substrate stack. The narrow openings of the reversed trenches 137 cause the non-conformal dielectric layer 139 to pitch off near the openings forming air gaps 140 when aspect ratios of the reversed trenches 137 are higher than a certain value. An aspect ratio of a trench generally refers to a ratio of trench height over trench width. Therefore, the air gaps 140 are formed within the reversed trenches 137 that are narrow. A solid layer of the non-conformal dielectric layer 139 may be formed in the reversed trenches 137 that are wide. As a result, the angled sidewalls provide natural selectiveness to the air gap formation. No patterning is needed, thus, saving cost.

The angle between the sidewalls of the reversed trenches 137 and the aspect ratio of the reversed trenches 137 may be adjusted to control the location of the air gaps 140. The angles between sidewalls of a trench may be tuned to control the vertical position of an air gap therein such that a subsequent CMP process does not break the seal of the air gap. For example, air gaps may form in trenches with smaller aspect ratio when angles between sidewalls of the trenches increase. In one embodiment, the air gaps 140 may be formed between adjacent conductive lines 135 that have a distance of between about 10 nm to about 200 nm from each other.

It is desirable to have the air gaps 140 positioned below a top surface of the conductive lines 135 so that the air gaps 140 are not exposed to a subsequent layer formed above after a CMP process. In one embodiment, the non-conformal ILD layer 139 may have a thickness of between about 100 Å to about 5000 Å.

In one embodiment, the non-conformal dielectric layer 139 is a low k dielectric material comprising carbon doped silicon dioxide, siliconoxycarbide (SiOₓC_{y}), or combinations thereof. Methods for forming the similar dielectric layer may be found in U.S. Pat. No. 6,054,379, entitled “Method of Depositing a Low K Dielectric with Organo Silane”, which is herein incorporated by reference.

In step 258, a chemical mechanical polishing (CMP) process is performed to the non-conformal dielectric layer 139 to expose the self-aligned capping layer 136, as shown in FIG. 2F. The air gaps 140 are still sealed after the CMP step.

In step 260, a dense dielectric barrier 141 may be deposited above the non-conformal dielectric layer 133, as shown in FIG. 2F. The dense dielectric barrier 141 is configured to prevent diffusion of metals, such as copper, in the conductive lines 135, and migration of species from the air gaps 140. The dense dielectric barrier 141 may comprises a thin low k dielectric barrier, such as silicon carbide (SiC), silicon carbide nitride (SiCN), boron nitride (BN), silicon boron nitride (SiBN), silicon boron carbide nitride (SiBCN), or combinations thereof. In one embodiment, the dense dielectric barrier 115 has a thickness of between about 20 Å to about 200 Å.

In step 262, an ILD layer 142 is deposited on the dense dielectric barrier 141, as shown in FIG. 2F. The ILD layer 142 is a low k dielectric with a k<2.7 providing a dielectric with between trench layers and dielectric layer for forming vias within. The ILD layer 142 may also be a low stress film. In one embodiment, the ILD layer 142 has a thickness of between about 100 Å to about 5,000 Å. The ILD layer 142 may be carbon doped silicon dioxide, siliconoxycarbide (SiOₓC_{y}), or combinations thereof. Method for forming the ILD layer 142 may be found in U.S. Pat. No. 6,054,379, entitled “Method of Depositing a Low K Dielectric with Organo Silane”, which is herein incorporated by reference.

In step 264, an etch stop layer 153 is formed on the ILD layer 142. The etch stop layer 153 is configured to protect the ILD layer 142 from wet etching chemistry used in forming air gaps in a subsequent trench layer above the ILD layer 142. In one embodiment, the etch stop layer 153 may comprise silicon carbide.

In step 266, a second dielectric layer 143 may be deposited over the etch stop layer 153, as shown in FIG. 2G. The second dielectric layer 143 is configured for forming trenches for a new trench layer therein. The second dielectric layer 143 may be similar to the first dielectric layer 105. In one embodiment, the second dielectric layer 143 comprises silicon dioxide.

In step 268, as shown in FIG. 2G, a dual damascene structure 144 may be formed in the ILD layer 142 and the second dielectric layer 143 for forming a new via layer and a new trench layer therein respectively. The dual damascene structure 144 may be formed using conventional damascene process except that etching of the second dielectric layer 143 are tuned so that trenches of the dual damascene structure 144 have angled sidewalls 145. A detailed description for forming a dual damascene structure may be found in United States Patent Application Publication No. 2006/0216926, entitled “Method of Fabricating a Dual Damascene Interconnect Structure”, which is herein incorporated by reference.

As shown in FIGS. 2G-2J, steps 244 to 258 may be repeated to form air gaps 152 between conductive lines 148 formed in the second dielectric layer 143. A conformal dielectric barrier film 146, similar to the conformal dielectric barrier film 133, may be deposited in the dual damascene structure 144 prior to deposition of a metallic diffusion barrier layer 147, similar to the metallic diffusion barrier 134. Conductive lines 148 may be formed in the damascene structure 144 after a punch through step so that the conductive lines 148 electrically are electrically connected to the conductive lines 135. A cap layer 149, similar to the cap layer 136, may be formed after a CMP process. The second dielectric layer 143 is then removed forming trenches 150 with angled sidewalls between the conductive lines 148. A non-conformal dielectric layer 151, similar to the non-conformal layer 139, is then deposited forming air gaps 152 within the trenches 150 that have a high aspect ratio. The non-conformal dielectric layer 151 is then subjected to a CMP process and are ready for subsequence processes.

Similar processes may be performed for each subsequent trench layer where air gaps are desired.

### Sequence 2

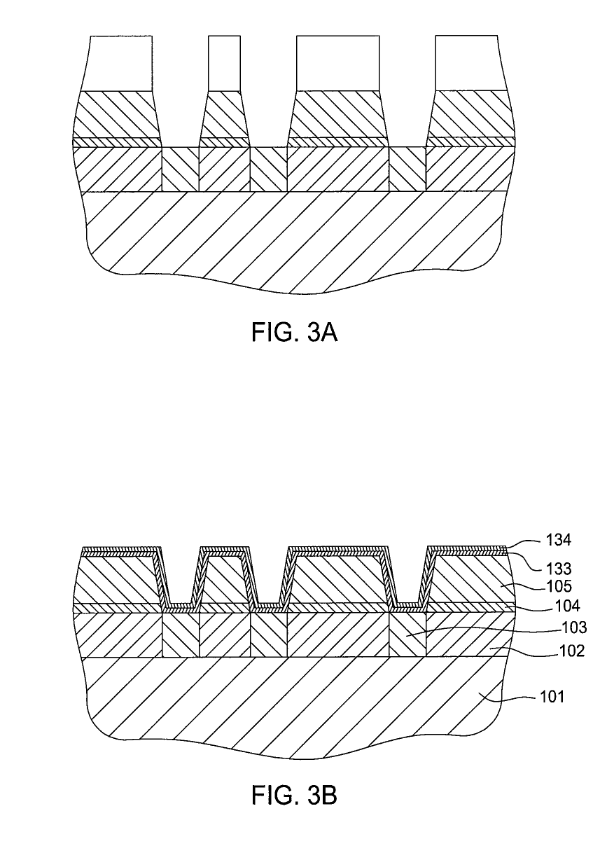

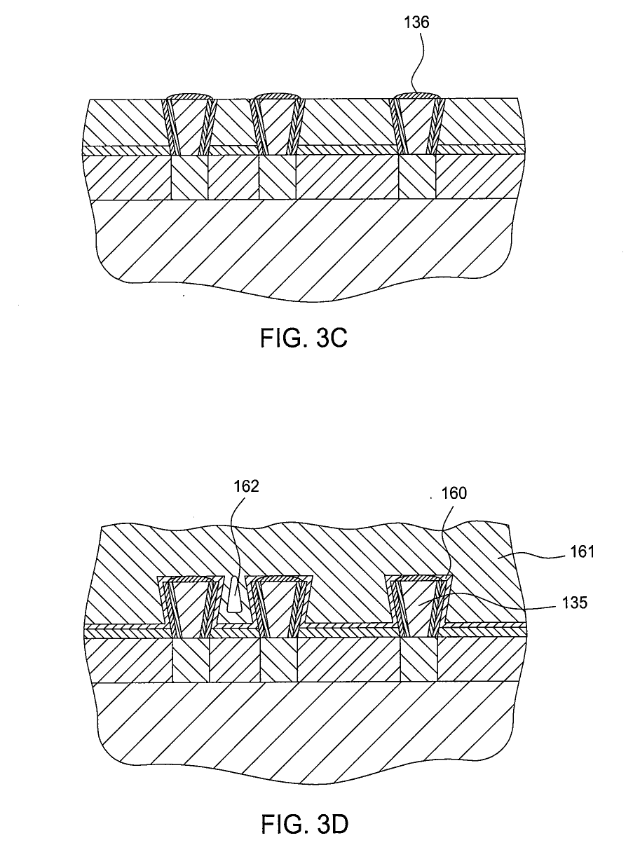

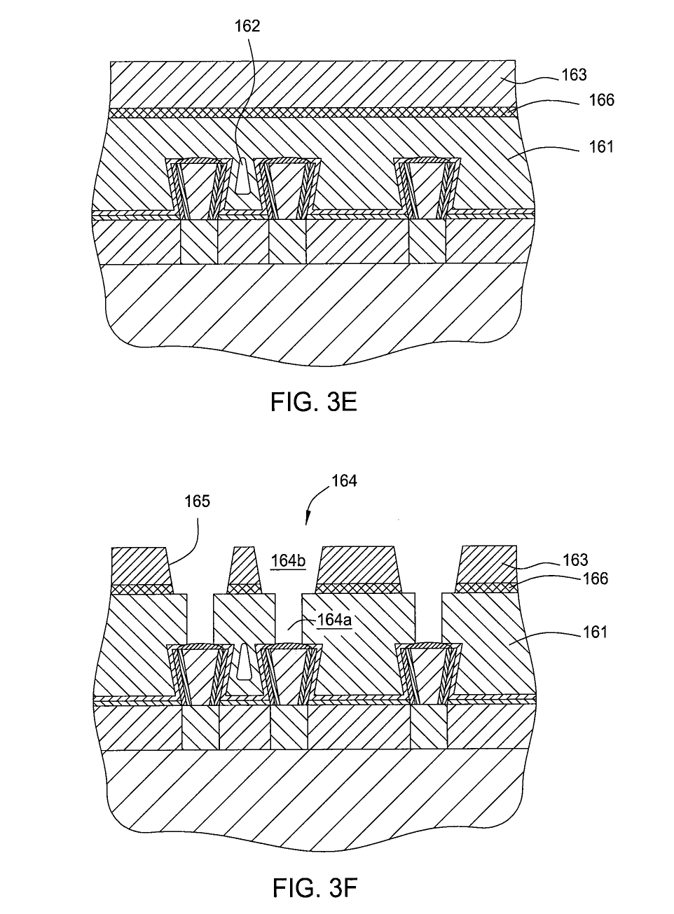

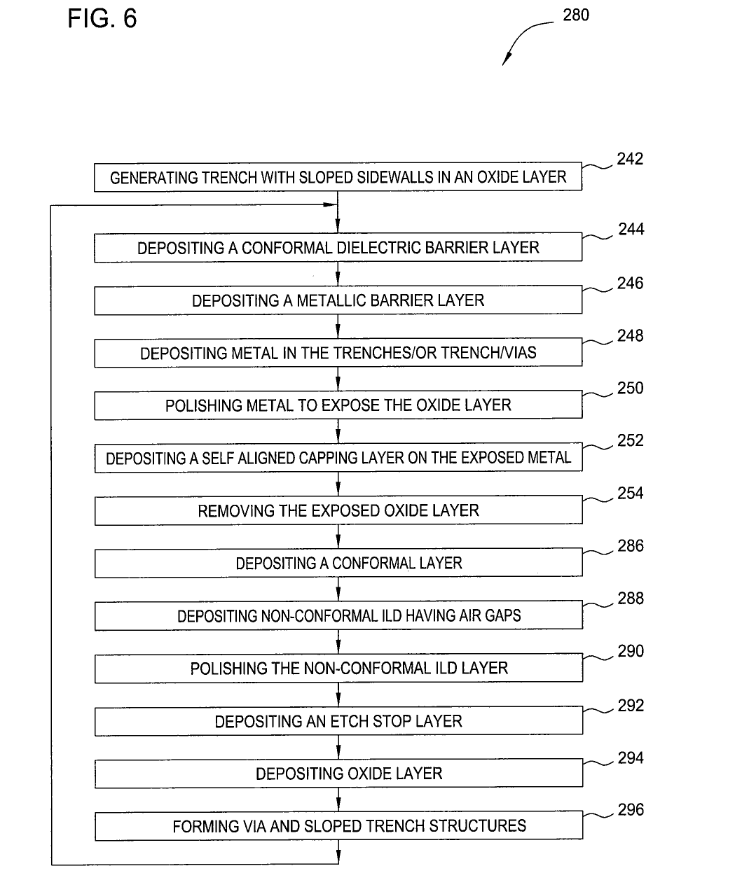

FIGS. 3A-3F schematically illustrate cross-sectional views of a substrate stack during a processing sequence 280 to form multilevel interconnect structures according to another embodiment of the invention. FIG. 6 illustrates processing steps in accordance with the processing sequence 280 shown in FIGS. 3A-3F.

The process sequence 280 comprises steps 242 to 254 that are similar to steps 242 to 254 in the processing sequence 240, as shown in FIGS. 3A-3C. The via layer 102 may be formed on the substrate 101. The conductive elements 103 are configured to electrically communicate with the devices formed in the substrate 101. The etch stop layer 104 is then deposited all over the via layer 102. The first dielectric layer 105 is deposited on the etch stop layer 104. The trenches 131 with angled sidewalls 132 are formed within the first dielectric layer 105. The conformal dielectric barrier film 133 and the metallic diffusion barrier 134 are deposited afterwards. The conductive lines 135 are formed in the trenches 131. A CMP process is performed followed by formation of the self-aligned capping layer 136 over the conductive lines 135. The first dielectric layer 105 is then removed forming reversed trenches 137 between the conductive lines 135. The reversed trenches 137 have angled sidewalls 138 with openings narrower than bottoms.

In step 286, following step 254, a conformal dielectric barrier film 160 is deposited over the reversed trenches 137 and the conductive lines 135, i.e. over the entire top surface, as shown in FIG. 3D. The conformal dielectric barrier film 160 is configured to serve as a barrier layer to protect metal structures, such as the conductive lines 135, and air gaps subsequently formed in the trenches 137. In one embodiment, the conformal dielectric barrier film 160 comprises a low k dielectric barrier material, for example silicon nitride (SiN), silicon carbide (SiC), silicon carbine nitride (SiCN), silicon boron nitride (SiBN), or combinations thereof. In one embodiment, the conformal dielectric barrier film 160 may have a thickness from about 10 Å to about 200 Å. Composition and formation of the conformal dielectric barrier film 160 may be similar to the conformal dielectric barrier film 107 described in step 204 of FIG. 4.

In step 288, a non-conformal ILD layer 161 is deposited over the conformal dielectric barrier film 160. Deposition of the non-conformal ILD layer 161 may be similar to deposition of the non-conformal ILD layer 139 described in step 256 of FIG. 5. Air gaps 162 may be formed in the non-conformal ILD layer 161 in the trenches 137 that have high aspect ratios. Since a CMP process following the deposition of the non-conformal ILD layer 161 does not polish the non-conformal ILD layer 161 all the way down to expose the conductive lines 136 or the self-aligned capping layer 136, location of the air gaps 162 may be not limited to be within the reversed trenches 137, thus, providing flexibility for the deposition process. As shown in FIG. 3D, the air gap 162 may locate higher than a top surface of the top of the conductive lines 135. In one embodiment, the non-conformal ILD layer 161 may have a thickness of between about 100 Å to about 5,000 Å.

In step 290, a CMP process is performed to the non-conformal ILD layer 161 so that the non-conformal ILD layer 161 is flat for the next step and has a thickness enough to accommodate the conductive lines 135 and a via layer for connecting the conductive lines 135 to a subsequent trench layer.

In step 292, an etch stop layer 166 is formed on the non-conformal ILD layer 161. The etch stop layer 166 is configured to protect the ILD layer 161 from wet etching chemistry used in forming air gaps in a subsequent trench layer above the ILD layer 161. In one embodiment, the etch stop layer 166 may comprise silicon carbide.

In step 294, a second dielectric layer 163 is deposited on the etch stop layer 166, as shown in FIG. 3E. The second dielectric layer 163 is configured to form trenches for a new trench layer. In one embodiment, the second dielectric layer 163 comprises silicon dioxide. In another embodiment, an etch stop layer may be deposited between the second dielectric layer 163 and the non-conformal ILD layer 161.

In step 296, as shown in FIG. 3F, a dual damascene structure 164 may be formed in the non-conformal ILD layer 161 and the second dielectric layer 163. The dual damascene structures 164 comprises vias 164a formed in the non-conformal ILD layer 161 and trenches 164b formed in the second dielectric layer 163. The dual damascene structure 164 may be formed using conventional damascene process except that etching of the second dielectric layer 163 is tuned so that trenches of the trenches 164b have angled sidewalls 165.

Steps 244-252 of the process sequence 280 may be repeated to complete formation of the new via layer and the new trench layer.

Similar process may be performed for each new via and trench layer where air gaps are desired in dielectric structures.

While the foregoing is directed to embodiments of the present invention, other and further embodiments of the invention may be devised without departing from the basic scope thereof, and the scope thereof is determined by the claims that follow.

What is claimed is:

1. A method for forming conductive lines in a semiconductor structure, comprising:
forming trenches in a first dielectric layer;
depositing a conformal dielectric barrier film in the trenches, wherein the conformal dielectric barrier film comprises a low k dielectric material;
depositing a metallic diffusion barrier film over the conformal low k dielectric layer;
depositing a conductive material to fill the trenches;
planarizing the conductive material to expose the first dielectric layer;
forming a self-aligned capping layer on the conductive material; and
removing the first dielectric layer using a wet etching chemistry, wherein the low k dielectric material in the conformal dielectric barrier serves as a barrier for the conductive material against the wet etching chemistry.

2. The method of claim 1, wherein the conformal dielectric barrier film comprises boron nitride (BN), silicon nitride (SiN), silicon carbide (SiC), silicon carbine nitride (SiCN), silicon boron nitride (SiBN), or combinations thereof.

3. The method of claim 2, wherein the conformal dielectric barrier film comprises a boron nitride (BN) film formed by a plasma enhanced chemical vapor deposition process.

4. The method of claim 1, wherein the conformal dielectric barrier film has a thickness of about 10Å to about 200 Å.

5. The method of claim 1, further comprising:
prior to removing the first dielectric layer, depositing a porous dielectric barrier over the conductive material and the first dielectric layer, wherein the first dielectric layer is removed using the wet etching chemistry through the porous dielectric barrier.

6. The method of claim 5, wherein the porous dielectric barrier comprises silicon carbide (SiC), silicon carbide nitride (SiCN), or combinations thereof, and without silicon-oxygen bonds.

7. The method of claim 6, wherein depositing the porous dielectric barrier comprises depositing a silicon carbide layer using a precursor comprising the combination of trimethylsilane (TMS, (CH₃)₃SiH) and ethylene (C₂H₄).

8. The method of claim 5, further comprising generating a pattern over the porous dielectric barrier to selectively remove the first dielectric layer.

9. The method of claim 1, further comprising:
depositing a non-conformal dielectric layer after removing the first dielectric layer, wherein forming the trenches comprises forming the trenches with angled sidewalls, the trenches are narrow at bottoms and wide at openings, removing the first dielectric layer forms reversed trenches around the conductive material, and depositing the non-conformal dielectric layer forms air gaps in the reversed trenches having an aspect ratio larger than particular value.

10. The method of claim 9, wherein an angle between opposing angled sidewalls of the trench is between about 5° to 130°.

11. (canceled)

12. The method of claim 9, further comprising depositing a conformal dielectric barrier film over the reversed trenches prior to depositing the non-conformal dielectric layer.

13. The method of claim 1, wherein forming the trenches comprises forming trench-via structures by a dual damascene process.

14. A method for forming a dielectric structure having air gaps, comprising:
forming trenches in a first dielectric layer, wherein the trenches are configured to retain conductive materials therein;
depositing a first conformal dielectric barrier film in the trenches;
depositing a first conductive material to fill the trenches;
planarizing the first conductive material to expose the first dielectric layer;
forming a first self-aligned capping layer on the conductive material;
depositing a first porous dielectric barrier over the first conductive material and the first dielectric layer; and
forming air gaps between the trenches by removing the first dielectric layer using a wet etching solution through the first porous dielectric barrier, wherein the first conformal dielectric barrier film serves as a barrier and etch stop against the wet etching solution.

15. The method of claim 14, further comprising generating a pattern over the first porous dielectric barrier to selectively remove the first dielectric layer.

16. The method of claim 14, wherein the first porous dielectric barrier comprises silicon carbide (SiC), silicon carbide nitride (SiCN), or combinations thereof, and without silicon monoxide (SiO).

17. The method of claim 14, wherein the first conformal dielectric barrier film comprises boron nitride (BN), silicon nitride (SiN), silicon carbide (SiC), silicon carbine nitride (SiCN), silicon boron nitride (SiBN), or the combinations thereof.

18. The method of claim 14, further comprising:
depositing a dense diffusion barrier on the first porous dielectric barrier after formation of the air gaps;
depositing an interlayer dielectric over the dense diffusion barrier layer, wherein the interlayer dielectric comprises a low k and low stress dielectric material;
depositing an etch stop layer on the interlayer dielectric;
forming a second dielectric layer on the etch stop layer;
forming trench-via structures in the interlayer dielectric and the second dielectric layer;
depositing a second conformal dielectric barrier film in the trench-via structures;
depositing a second conductive material to fill the trench-via structures;
planarizing the second conductive material to expose the second dielectric layer;
forming a second self-aligned capping layer on the second conductive material;
depositing a second porous dielectric barrier over the second conductive material and the second dielectric layer; and
forming air gaps by removing the second dielectric layer using the wet etching solution through the second porous dielectric barrier, wherein the second conformal dielectric barrier film serves as a barrier and etch stop against the wet etching solution.

19. The method of claim 14, wherein depositing the first conductive material comprising:
forming a metallic diffusion barrier on the first conformal dielectric barrier;
forming a seed layer on the metallic diffusion barrier; and
filling the trenches with the conductive material.

20. A method for forming a dielectric structure having air gaps, comprising:
forming trenches in a first dielectric layer, wherein the trenches having angled sidewalls and are narrow at bottoms and wide at openings;
depositing a first conformal dielectric barrier film in the trenches;
depositing a first conductive material to fill the trenches;
planarizing the first conductive material to expose the first dielectric layer;
removing the first dielectric layer to form reversed trenches around the first conductive material, wherein the reversed trenches have angled sidewalls and are narrow at openings and wide at bottoms; and
forming air gaps by depositing a first non-conformal dielectric layer in the reversed trenches, wherein the air gaps are formed at least partially in the reversed trenches having an aspect ratio larger than a particular value.

21. The method of claim 20, further comprising depositing a second conformal dielectric barrier film over the reversed trenches prior to depositing the first non-conformal dielectric layer.

22. The method of claim 21, further comprising:
planarizing the first non-conformal dielectric layer without breaking the air gaps in the first non-conformal dielectric layer;
depositing an etch stop layer over the first non-conformal dielectric layer;
depositing a second dielectric layer over the etch stop layer; and
forming dual damascene structures in the first non-conformal dielectric layer and the second dielectric layer.

23. The method of claim 22, wherein the damascene structures comprise trenches with angled sidewalls and are narrow at bottoms and wide openings, and further comprising:
depositing a third conformal dielectric barrier film in the damascene structures;
depositing a second conductive material to fill the damascene structures;
planarizing the second conductive material to expose the second dielectric layer;
removing the second dielectric layer to form reversed trenches around the second conductive material, wherein the reversed trenches have angled sidewalls and are narrow at openings and wide at bottoms; and
forming air gaps around the second conductive material by depositing a second non-conformal dielectric layer in the reversed trenches around the second material, wherein the air gaps are formed at least partially in the reversed trenches having an aspect ratio larger than a particular value.

24. The method of claim 20, further comprising:
planarizing the first non-conformal dielectric layer without breaking the air gaps in the first non-conformal dielectric layer;
depositing a dense dielectric barrier above the first non-conformal dielectric layer;
depositing an interlayer dielectric above the dense dielectric barrier;
depositing an etch stop layer over the interlayer dielectric;
depositing a second dielectric layer above the etch stop layer; and
forming dual damascene structures in the interlayer dielectric layer and the second dielectric layer.

25. The method of claim 24, wherein the damascene structures comprise trenches with angled sidewalls and are narrow at bottoms and wide openings, and further comprising:
depositing a second conformal dielectric barrier film in the damascene structures;
depositing a second conductive material to fill the damascene structures;
planarizing the second conductive material to expose the second dielectric layer;
removing the second dielectric layer to form reversed trenches around the second conductive material, wherein the reversed trenches have angled sidewalls and are narrow at openings and wide at bottoms; and
forming air gaps around the second conductive material by depositing a second non-conformal dielectric layer in the reversed trenches around the second material, wherein the air gaps are formed at least partially in the reversed trenches having an aspect ratio larger than a particular value.
